(19) United States
(12) Patent Application Publication
(10) Pub. No.: US 2026/0025965 A1
(43) Pub. Date: Jan. 22, 2026

(54) DISPOSITION ASSISTANCE DEVICE AND DISPOSITION ASSISTANCE METHOD FOR BACKUP MEMBER

(71) Applicant: FUJI CORPORATION, Chiryu (JP)

(72) Inventor: Kenji NAKAI, Anjo-shi (JP)

(73) Assignee: FUJI CORPORATION, Chiryu (JP)

(21) Appl. No.: 18/996,457

(22) PCT Filed: Sep. 6, 2022
(86) PCT No.: PCT/JP2022/033398

§ 371 Date: Jan. 17, 2025

(51) Int. Cl. H05K 13/04; H05K 13/08

(52) U.S. Cl. CPC H05K 13/0404; H05K 13/0812

(57) ABSTRACT

A disposition assistance device for a backup member, the disposition assistance device being to be applied to a board work machine configured to automatically exchange a tool among multiple tool stations provided in the machine, the board work machine including multiple work heads configured to execute a predetermined board work using the tool on a board supported by the backup member, the disposition assistance device including an acquisition section configured to acquire an accommodation position where a picker capable of holding the backup member is accommodated in the multiple tool stations; and a setting section configured to set the work head that executes a disposition work of the backup member using the picker according to the accommodation position of the picker.

### TECHNICAL FIELD

The present disclosure relates to a disposition assistance device and a disposition assistance method for a backup member.

### BACKGROUND ART

The backup member is applied to a backup device that supports a board positioned at a predetermined position in a conveyance direction from below in a predetermined board work. Patent Literature 1 discloses a component mounter that includes a backup device and mounts a component on a board by board work. In the disposition work of the backup member, the disposition position and the like are appropriately set according to the board work scheduled to be executed and the type of the board. A picker capable of holding the backup member is used for the disposition work of the backup member. The picker is provided on a work head or is detachably attached to the work head.

### CITATION LIST

### Patent Literature

Patent Literature 1: WO 2004/103054

### BRIEF SUMMARY

### Technical Problem

In a case in which the board work machine includes multiple work heads and only one of the work heads is provided with a picker, the work head executes the disposition work of the backup member. Here, in a case in which the multiple work heads are used for each of multiple different types of board work, the number of times of execution of the disposition work of the backup member and the required time of the disposition work may be biased among the multiple backup devices. In this case, if one of the work heads is caused to execute the disposition work, the work of the other of the work heads are in a standby state, and there is a possibility that the production efficiency decreases.

An object of the present description is to provide a disposition assistance device and a disposition assistance method for a backup member capable of efficiently executing a disposition work of a backup member using a picker and preventing a decrease in production efficiency.

### Solution to Problem

The present description discloses a disposition assistance device for a backup member, the disposition assistance device being to be applied to a board work machine configured to automatically exchange a tool among multiple tool stations provided in the machine, the board work machine including multiple work heads configured to execute a predetermined board work using the tool on a board supported by the backup member, the disposition assistance device including an acquisition section configured to acquire an accommodation position where a picker capable of holding the backup member is accommodated in the multiple tool stations: and a setting section configured to set the work head that executes a disposition work of the backup member using the picker according to the accommodation position of the picker.

The present description discloses a disposition assistance method for a backup member, the disposition method being to be applied to a board work machine configured to automatically exchange a tool among multiple tool stations provided in the machine, the board work machine including multiple work heads configured to execute a predetermined board work using the tool on a board supported by the backup member, the disposition assistance method including an acquisition step of acquiring an accommodation position where a picker capable of holding the backup member is accommodated in the multiple tool stations: and a setting step of setting the work head that executes a disposition work of the backup member using the picker according to the accommodation position of the picker.

### Advantageous Effects

According to such a configuration, the work head that executes the disposition work is set according to the accommodation position of the picker, and thus the disposition work of the backup member can be efficiently executed. As a result, it is possible to prevent a decrease in production efficiency.

### BRIEF DESCRIPTION OF DRAWINGS

FIG. 1 is a schematic diagram illustrating a production system to which a disposition assistance device of a backup member is applied.

FIG. 2 is a schematic diagram illustrating a configuration of a component mounter.

FIG. 3 is a side view illustrating a backup device of a board conveyance device.

FIG. 4 is a plan view illustrating the backup device of the board conveyance device.

FIG. 5 is an enlarged plan view of a part of a nozzle station.

FIG. 6 is a functional block diagram of the disposition assistance device.

FIG. 7 is a flowchart illustrating a disposition assistance process.

FIG. 8 is a flowchart illustrating an example of a preparation process in the disposition assistance process.

FIG. 9 is a diagram illustrating a production plan and disposition information.

FIG. 10 is a diagram illustrating a required time of the production process and a setup work for each lane.

### DESCRIPTION OF EMBODIMENTS

### 1. Overview of Disposition Assistance Device 80 of Backup Member 50

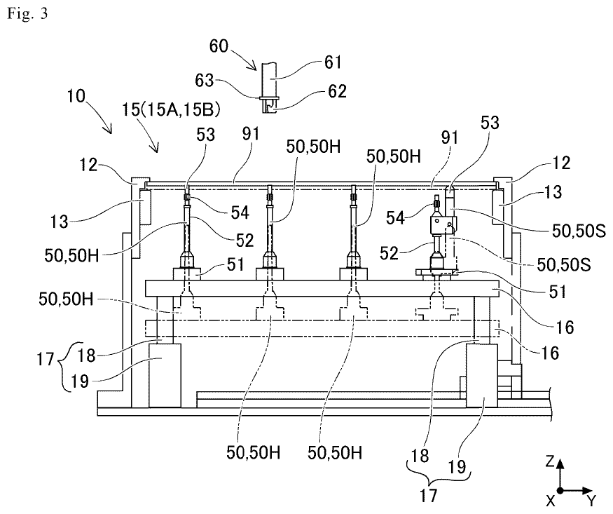

Disposition assistance device 80 assists a disposition work of backup member 50 applied to backup device 15 (see FIG. 3) that supports board 91 from below. The disposition work of backup member 50 is executed, for example, in a setup work for the board work as necessary. In the present embodiment, an aspect will be described as an example in which disposition assistance device 80 is applied to production system Sy including component mounter 2 that serves as a board work machine and that includes backup device 15.

### 2. Configuration of Production Line Ln

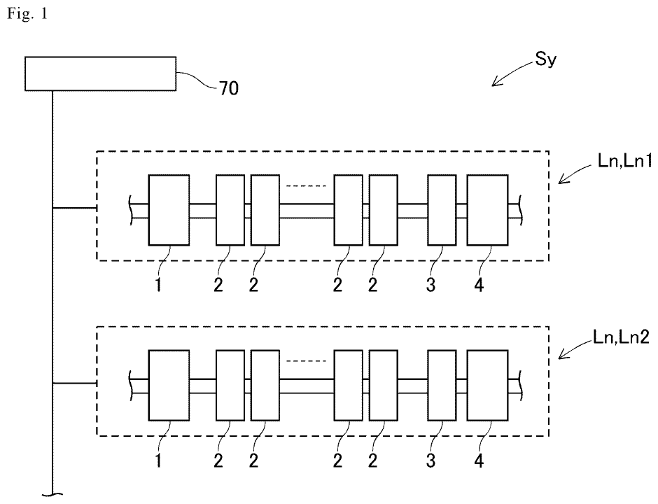

Component mounter 2 executes a mounting process of mounting a component on board 91 as a predetermined board work. As illustrated in FIG. 1, production line Ln is configured such that multiple board work machines are installed in a conveyance direction of board 91. Each of the multiple board work machines is communicably connected to host computer 70, which collectively controls production line Ln.

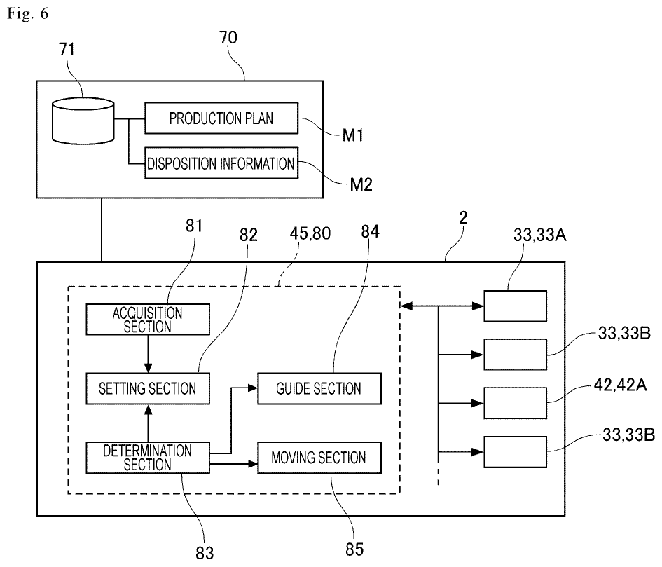

As illustrated in FIG. 6, host computer 70 includes storage section 71. Storage section 71 stores production plan M1 and disposition information M2. Production plan M1 indicates the type and production order of a board product scheduled to be produced. Disposition information M2 indicates the disposition position of backup member 50 set for the board work corresponding to the production of the board product. Disposition information M2 is downloaded in response to a request from the board work machine of each production line Ln and stored in a control device of the board work machine. Details of production plan M1 and disposition information M2 will be described later.

Production line Ln includes printer 1, multiple component mounters 2, reflow oven 3, and inspector 4 as multiple board work machines. Printer 1 prints paste-like solder at a mounting position of the components on board 91 that is conveyed in. Each of multiple component mounters 2 mounts the component on board 91 conveyed from an upstream side of production line Ln. A configuration of component mounter 2 will be described later. Reflow oven 3 heats board 91 conveyed from the upstream side of production line Ln, melts the solder on board 91, and performs soldering. Inspector 4 inspects whether an appearance or a function of the board product produced by production line Ln is normal.

In the present embodiment, multiple production lines Ln (Ln1, Ln2, . . . ) may be configured in a factory of the board product. Each of multiple production lines Ln may have a configuration appropriately added or changed depending on, for example, the type of board product to be produced. Specifically, a board work machine such as a buffer device for temporarily holding board 91 conveyed, a board supply device, a board flipping device, various types of inspection devices, a shield mounting device, an adhesive application device, or an ultraviolet ray irradiation device, can be installed in multiple production lines Ln as appropriate.

### 3. Configuration of Component Mounter 2

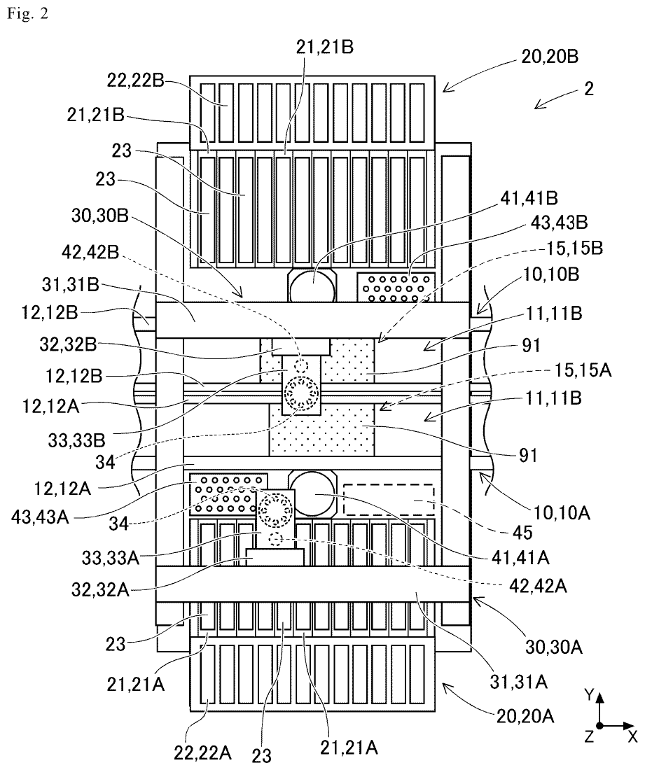

As illustrated in FIG. 2, component mounter 2 includes two sets of work units including board conveyance device 10, component supply device 20, component transfer device 30, part camera 41, board camera 42, and nozzle station 43, and control device 45. In the following description, a front-rear direction of component mounter 2 (a direction from bottom to top in FIG. 2) that is a horizontal direction is set to a Y direction, a left-right direction of component mounter 2 (a direction from left to right in FIG. 2) that is a horizontal direction intersecting the Y direction is set to an X direction, and a vertical direction (a direction from the back to the front in FIG. 2) orthogonal to the X direction and the Y direction is set to a Z direction.

The two sets of the work units are disposed side by side in the Y direction and are configured to be line-symmetrical at a center portion in the Y direction. Hereinafter, one side (lower side in FIG. 2) on which the two sets of the work units are installed is referred to as first side S1, the other side (upper side in FIG. 2) is referred to as second side S2, and the configuration of the work unit of first side S1 will be described. In FIG. 2, in order to distinguish the two sets of units, first side S1 side is denoted by “A” and second side S2 side is denoted by “B” in the symbol of each configuration.

### 3-1. Board Conveyance Device 10

Board conveyance device 10 is configured with conveyance mechanisms 11 or the like installed side by side in the Y direction. Each of conveyance mechanisms 11 includes pair of guide rails 12 and pair of conveyor belts 13. Pair of guide rails 12 extend in the conveyance direction (X direction) of the board, and support a peripheral edge of board 91 placed and conveyed on conveyor belt 13. At least one of pair of guide rails 12 is provided on the base so as to be movable in the Y direction.

Board conveyance device 10 subsequently conveys board 91 in the conveyance direction and positions board 91 at a predetermined position in the machine. Board conveyance device 10 includes backup device 15 that clamps positioned board 91. Detailed configurations of board conveyance device 10 and backup device 15 will be described later. After executing the component mounting process, board conveyance device 10 conveys out board 91 to the outside of component mounter 2.

### 3-2. Component Supply Device 20

Component supply device 20 has multiple slots 21 and multiple reel holding sections 22 disposed side by side in the X direction. Feeder 23 is detachably set in each of multiple slots 21. Feeders 23 feed and move a carrier tape in which multiple components are accommodated, so as to collectably supply the components. Reel holding section 22 holds the reel on which the carrier tape is wound in an exchangeable manner. Component supply device 20 may supply, for example, relatively large components in a state in which the components are arranged on a tray placed on a pallet. In the above configuration, component supply device 20 supplies components by pulling out predetermined pallets from an accommodation device that accommodates multiple pallets in accordance with a mounting process.

### 3-3. Component Transfer Device 30

Component transfer device 30 transfers the component supplied by component supply device 20 to a predetermined mounting position on board 91 conveyed into the machine by board conveyance device 10. Head driving device 31 of component transfer device 30 moves moving table 32 in the horizontal direction (the X direction and the Y direction) with a linear motion mechanism. Mounting head 33 is fixed to moving table 32 in an exchangeable manner by a clamp member (not illustrated). Various tools are detachably attached to mounting head 33. The tool includes suction nozzle 34 for holding the component and picker 60 for holding backup member 50 described later (see FIG. 3).

Suction nozzle 34 picks up and holds a component by using supplied negative pressure air. The lifting and lowering position and angle of suction nozzles 34 with respect to mounting head 33 and a supply state of a negative pressure air are controlled. A chuck that clamps a component can be attached to mounting head 33 as another tool. Picker 60 that holds backup member 50 may be detachably attached to mounting head 33, for example, by being engaged with a predetermined portion of backup member 50. As described above, component transfer device 30 is capable of holding backup member 50 in addition to the component, and functions as a movement device that moves backup member 50. Component transfer device 30 is used for disposition work (including increase/decrease and position change) of backup member 50.

As described above, component mounter 2 of the present embodiment includes a facing robot in which multiple mounting heads 33 (first mounting head 33A and second mounting head 33B) are disposed to face each other in the Y direction. The movable regions of multiple mounting heads 33 overlap each other, and are configured to be accessible to a side (for example, second side S2) opposite to a side (for example, first side S1 of first mounting head 33A) to which mounting head 33 is close, and can alternately work on same board 91. Multiple mounting heads 33 are subjected to non-interference control so that interference does not occur in a region where the movable regions overlap each other.

### 3-4. Part Camera 41 and Board Camera 42

Part camera 41 and board camera 42 are digital imaging devices each having an imaging element such as a CMOS. Part camera 41 and board camera 42 perform imaging based on a control signal and transmit image data acquired through the imaging. Part camera 41 is configured to image the component held by suction nozzle 34 from below. Board camera 42 is provided on moving table 32 to be movable in the horizontal directions integrally with mounting head 33. Board camera 42 is configured to image board 91 from above.

In addition to using a surface of board 91 as an imaging target, board camera 42 can use various devices or the like as the imaging target as long as various devices are within a movable range of moving table 32. For example, in the present embodiment, as illustrated in FIG. 5, board camera 42 can image reference mark 431 and barcode 432 attached to nozzle station 43, which will be described later, and a tool (suction nozzle 34 and picker 60) accommodated in nozzle station 43 while being contained in a camera visual field. As described above, board camera 42 can be used to image different imaging targets in order to acquire the image data used for various pieces of image processing.

### 3-5: Nozzle Station 43

Nozzle station 43 is provided inside component mounter 2. Nozzle station 43 is a tool station that accommodates various tools used for the board work by component mounter 2 as the board work machine. In the present embodiment, nozzle station 43 detachably holds multiple suction nozzles 34 and pickers 60. In an exchange process of suction nozzle 34, nozzle station 43 holds suction nozzle 34 detached from mounting head 33 and also detachably holds other suction nozzles 34. As a result, component mounter 2 is configured to automatically exchange suction nozzle 34 in accordance with the type of the component of the mounting target during the execution of the mounting process.

Nozzle station 43 is detachably installed on the base of component mounter 2. As illustrated in FIG. 5, reference mark 431 and barcode 432 are provided on the upper surface of nozzle station 43. Reference mark 431 indicates a reference position on the upper surface of nozzle station 43, and is attached so as to have a prescribed positional relationship with respect to an accommodation section that individually accommodates the tool. Barcode 432 indicates identification information of nozzle station 43. In the identification information, the identification information and the accommodation position of the tool accommodated in nozzle station 43 are associated with each other. The accommodation position is indicated by, for example, a relative position of the accommodation section with respect to the reference position.

### 3-6. Control Device 45

Control device 45 includes mainly of CPU, various types of memory, and a control circuit. Control device 45 executes a mounting process of mounting a component on board 91. In the mounting process, control device 45 controls the operation of component transfer device 30 based on information output from various sensors, the results of image processing, a control program stored in advance, or the like. Thus, positions and angles of multiple suction nozzles 34 supported by mounting head 33 are controlled. Control device 45 executes a disposition work including addition or removal of backup member 50 used for board conveyance device 10 to support board 91 from below in the mounting process, and changing of the position of backup member 50.

Control device 45 stores disposition information M2 downloaded from host computer 70. As illustrated in FIG. 9, “disposition information M2” indicates the disposition position of backup member 50 set for the board work (corresponding to the type of board product) scheduled to be executed. Disposition information M2 indicates the disposition position (P111, P112, P113, . . . ) of backup member 50 and the type (pin type: hard, soft) of backup member 50. In addition to the above, disposition information M2 may include an allowable error of the disposition of backup member 50 with respect to the disposition position. Disposition information M2 is set in advance according to the type (including the size and the hardness) of board 91, the type (including the mounting position of the component) of the board product to be produced, the production process, and the like.

### 4. Detailed Configurations of Board Conveyance Device 10 and Backup Device 15

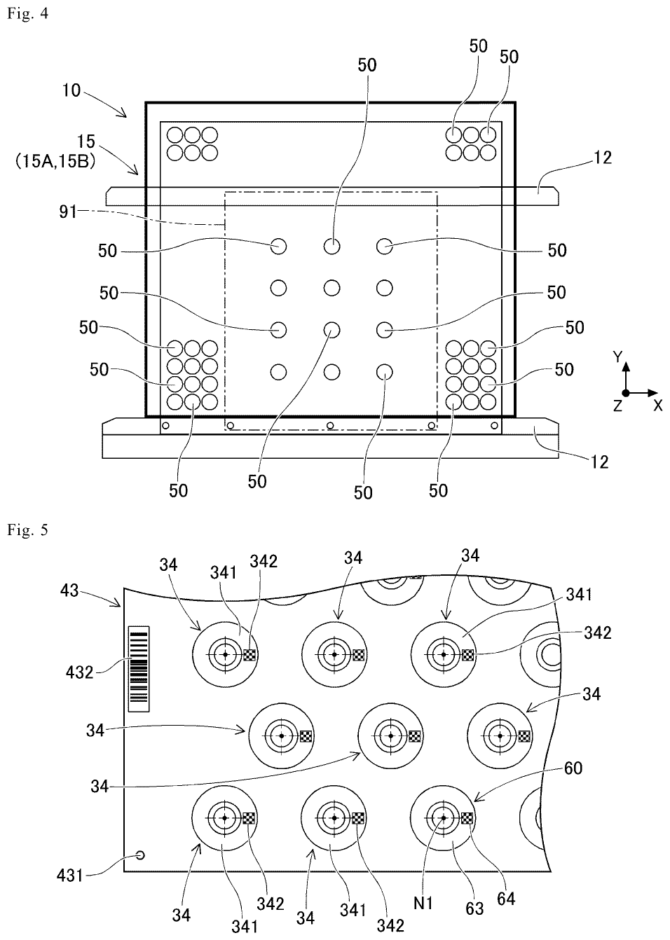

Component mounter 2 of the present embodiment is a double-track conveyor type including multiple conveyance mechanisms 11A and 11B. Pair of guide rails 12 configuring conveyance mechanisms 11 are provided on the base so as to be relatively movable in the Y direction. Consequently, conveyance mechanism 11 adjusts a gap between pair of guide rails 12 in accordance with dimensions of board 91 in the Y direction (see FIG. 4).

Backup device 15 supports board 91 conveyed by conveyance mechanisms 11 from below, and clamps board 91 between pair of guide rails 12. In the present embodiment, backup device 15 supports board 91 by contacting backup member 50 with a lower surface of board 91. Therefore, backup device 15 clamps board 91 between pair of guide rails 12 and maintains a height of a portion coming into contact with backup member 50, thereby preventing board 91 from bending.

As illustrated in FIG. 3, backup device 15 includes backup plate 16 and lifting and lowering device 17. Backup plate 16 is disposed to face the lower surface of board 91 positioned by conveyance mechanisms 11. Backup plate 16 is provided on the base to be liftable and lowerable in the Z direction. In the present embodiment, backup plate 16 is formed in a rectangular shape. Backup member 50 is detachably disposed on an upper surface of backup plate 16.

Lifting and lowering device 17 lifts and lowers backup plate 16 with respect to the base. In the present embodiment, lifting and lowering device 17 is configured with multiple air cylinders each having rod 18 and cylinder main body 19. Rods 18 of the respective air cylinders are detachably fixed to the four corners of backup plate 16. Cylinder main body 19 of each air cylinder advances and retracts rod 18 in the Z direction in accordance with the air pressure.

Lifting and lowering device 17 of backup device 15 retracts backup member 50 downward from the rear surface of board 91 when board 91 is conveyed in or out. Consequently, lifting and lowering device 17 lowers backup plate 16 to a preparation height at which a component (rear surface component) mounted on the rear surface of board 91 and backup member 50 do not interfere with each other (indicated by a two-dot chain line in FIG. 3). Lifting and lowering device 17 lifts backup plate 16 to a backup height (indicated by a solid line in FIG. 3) during execution of the mounting process. Consequently, backup device 15 pushes up and supports board 91 from below.

Here, backup member 50 is detachably disposed on the upper surface of backup plate 16. In the present embodiment, backup member 50 includes hard pin 50H having support section 53 formed of a relatively hard member (for example, a metal member) at a distal end thereof, and soft pin 50S having support section 53 formed of a relatively soft member (for example, a rubber member) at a distal end thereof. In backup member 50, support section 53 is connected to base portion 51 via body portion 52. In backup member 50, a magnet is embedded in base portion 51 located at a lower end, and backup member 50 is fixed to backup plate 16 having good magnetic force. In backup member 50, engaging section 54 having the same shape is formed above base portion 51. Engaging section 54 engages with picker 60 attached to mounting head 33.

Picker 60 includes main body portion 61 and collection section 62. Main body portion 61 is formed in a cylindrical shape as a whole. Main body portion 61 is formed to be attachable to mounting head 33 similarly to suction nozzle 34. Collection section 62 is provided at the lower end of main body portion 61. Collection section 62 is engaged with engaging section 54 of hard pin 50H and engaging section 54 of soft pin 50S. In order to maintain the state of holding hard pin 50H or soft pin 50S, picker 60 presses the distal end of engaging section 54 by the elastic force of the elastic member provided inside main body portion 61, and biases the lower end portion of engaging section 54 toward collection section 62.

### 5. Overview of Disposition Work of Backup Member 50

Control device 45 of component mounter 2 executes the disposition work of backup member 50 based on disposition information M2 by using component transfer device 30 functioning as the movement device of backup member 50, for example, before executing the mounting process (next board work) corresponding to a predetermined board product. The purpose of executing the disposition work is to handle, for example, the type of backup member 50 and a position where backup member 50 is to be disposed that may change according to dimensions of board 91 or the number or positions of components to be mounted.

When the type of board product to be produced is changed, component mounter 2 executes the disposition work of backup member 50 as one of the setup work as necessary. This disposition work includes, in addition to fixing backup member 50 to backup plate 16 located below board 91, removal of backup member 50 (movement to a retract region where spare backup member 50 that is not used for supporting board 91 is placed).

When executing the disposition work of backup member 50, control device 45 attaches picker 60 capable of holding backup member 50 to mounting head 33. Picker 60 is accommodated in nozzle station 43 and exchanged with suction nozzle 34 attached to mounting head 33. Control device 45 drives component transfer device 30 to appropriately move target backup member 50 to a position indicated by disposition information M2.

Here, component mounter 2 configured as described above can automatically execute all the disposition work of backup member 50 in the setup work. Specifically, in the setup work of the next mounting process, control device 45 individually moves backup member 50 using picker 60 based on disposition information M2, the position information indicating the current position of each backup member 50 used in the current mounting process, and spare information indicating the current position of spare backup member 50 placed in the retract region.

After the disposition of all backup members 50 is completed, control device 45 causes the nozzle station to accommodate picker 60 and ends the disposition work. In addition, control device 45 updates and stores the position information and the spare information indicating the target region in which backup member 50 is placed inside component mounter 2 and the current position of backup member 50 disposed in the retract region. Accordingly, control device 45 can perform the disposition work of backup member 50 without the movement by the worker.

In the configuration including the multiple work heads (mounting heads 33) as in component mounter 2 of the present embodiment, pickers 60 are attached to any of the work heads, and thus the disposition work of backup member 50 required on the opposite side can be performed instead. In this way, by making picker 60 detachable, in component mounter 2 including the facing robot, the work head applicable to the disposition work can be selected, thereby improving the work flexibility.

Here, in a board work machine (for example, component mounter 2) including multiple work heads, the multiple work heads may be used for each of multiple different types of board work. In such a case, the number of times of execution of the disposition work of the backup member and the required time of the disposition work may be biased among the multiple backup devices. That is, when the production process proceeds independently on first side S1 and second side S2, the time and the number of times when the disposition work is necessary are different depending on the degree of progress, and when the work head that executes the disposition work is fixed to one thereof, the other thereof is in a pause state, and there is a concern that the production efficiency is reduced.

Therefore, the present embodiment adopts a configuration in which the disposition work of backup member 50 using picker 60 is efficiently executed to prevent a decrease in production efficiency. Specifically, as illustrated in FIG. 6, disposition assistance device 80 that assists the disposition work of backup member 50 is incorporated in control device 45. Disposition assistance device 80 can simplify the setting of the work head for executing the disposition work, and can set the work head suitable for the disposition work to improve the efficiency of the setup work.

### 6. Detailed Configuration of Disposition Assistance Device 80

### 6-1. Acquisition Section 81

Disposition assistance device 80 includes acquisition section 81. Acquisition section 81 acquires accommodation positions N1 where pickers 60 are accommodated in multiple nozzle stations 43 serving as the tool stations. In the present embodiment, acquisition section 81 executes reading processing of codes attached to multiple tools (suction nozzles 34 and pickers 60) accommodated in multiple nozzle stations 43.

Here, as illustrated in FIG. 5, code 342 indicating identification information of suction nozzle 34 is attached to flange 341 of suction nozzle 34. Code 64 indicating identification information of picker 60 is attached to flange 63 of picker 60. The identification information is associated with the type of the tool, the maintenance record, and the like. Acquisition section 81 acquires the types of the multiple tools including picker 60 based on the result of the reading processing.

In the reading processing, for example, a dedicated code reader may be provided above nozzle station 43. In the present embodiment, acquisition section 81 executes the reading processing of code 64 using board camera 42 provided to be movable integrally with mounting head 33. Acquisition section 81 acquires accommodation position N1 of the tool (suction nozzle 34 and picker 60) based on the position of board camera 42 when board camera 42 images codes 342 and 64.

Specifically, in the reading processing, board camera 42 is moved above the positions where codes 342 and 64 of the tools accommodated in nozzle station 43 are attached, and imaging is performed. As described above, by repeating the movement and the imaging of board camera 42, the presence or absence of the tool and the type of the tool when the tool is present are acquired for each of the multiple accommodation sections of nozzle station 43. Further, in which accommodation section the tool is accommodated is determined from the position of board camera 42 at the time of imaging. Thus, whether picker 60 is accommodated is determined, and if picker 60 is accommodated, accommodation position N1 of picker 60 is determined.

Further, as long as acquisition section 81 can acquire accommodation position N1 of picker 60 in the machine, various aspects other than the above can be adopted. For example, setting information in which a tool including picker 60 is automatically or manually set in a tool station outside the machine and installation information in which the tool station is automatically or manually installed in the machine may be externally input to determine the accommodation position of picker 60 in the machine.

### 6-2. Setting Section 82

Disposition assistance device 80 includes setting section 82. Setting section 82 sets mounting head 33 that executes the disposition work of backup member 50 using picker 60 according to accommodation position N1 of picker 60. In the present embodiment, setting section 82 sets which of two mounting heads 33A and 33B is to execute the disposition work according to whether picker 60 is accommodated in nozzle station 43A on first side S1 or nozzle station 43B on second side S2.

Various aspects can be adopted for the setting in consideration of accommodation position N1 of picker 60 by setting section 82. For example, setting section 82 may set one of multiple mounting heads 33 that is closer to accommodation position N1 of picker 60 as mounting head 33 that preferentially performs the disposition work. According to such a configuration, for example, the worker can designate mounting head 33 to be subjected to the disposition work by the disposition of picker 60. That is, it is possible to easily perform designation without designating component mounter 2 or host computer 70, thereby improving efficiency.

### 6-3. Determination Section 83

Disposition assistance device 80 may further include determination section 83. Based on production plan M1 and disposition information M2, determination section 83 executes a determination process of mounting head 33 suitable for each of the multiple disposition works among multiple mounting heads 33. Specifically, determination section 83 first recognizes what kind of mounting process is scheduled to be executed on first side S1 and second side S2 for what period based on production plan M1 (see FIG. 9).

Here, as illustrated in FIG. 9, production plan M1 indicates, for each of first side S1 and second side S2, types of board products scheduled to be produced (R11, R12, R13, . . . , R21, R22, R23, . . . ), the scheduled production volume (V11, V12, V13, . . . , V21, V22, V23, . . . ), and the production order thereof. Based on disposition information M2, determination section 83 recognizes the content of the disposition work of backup member 50 required in the setup work of each mounting process. This is because it is considered that there is a case where the disposition work is unnecessary even in different types of mounting processes, and there is a case where the disposition work of backup member 50 is necessary depending on the disposition state of the components on the rear surface side even in similar mounting processes.

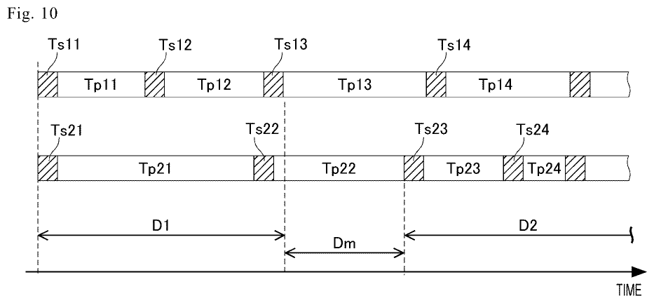

FIG. 10 illustrates the required time (Tp11, Tp12, Tp13, . . . ) of the mounting process scheduled to be executed in first side S1, and the required time (Ts11, Ts12, Ts13, . . . ) of the setup work corresponding thereto. Further, FIG. 10 illustrates the required time (Tp21, Tp22, Tp23, . . . ) of the mounting process scheduled to be executed in second side S2, and the required time (Ts21, Ts22, Ts23, . . . ) of the setup work corresponding thereto.

Determination section 83 determines first period D1 more suitable for the disposition work using picker 60 by first mounting head 33A and second period D2 more suitable for the disposition work using picker 60 by second mounting head 33B. Determination section 83 designates nozzle station 43 in which picker 60 is to be accommodated before the execution of the disposition work based on the result of the determination process. In the present embodiment, as illustrated in a right column of FIG. 9, determination section 83 designates nozzle stations 43 by sides (S1 and S2) corresponding to respective nozzle stations 43.

### 6-4. Guide Section 84

Disposition assistance device 80 may further include guide section 84. Guide section 84 guides nozzle station 43 accommodating picker 60 among multiple nozzle stations 43 in the setup work before production to the worker performing the setup change based on the result of the determination process. Here, since setting section 82 sets mounting head 33 that executes the disposition work using picker 60 according to accommodation position N1 of picker 60, guide section 84 guides nozzle station 43 in which picker 60 is to be accommodated to the worker in order to suitably reflect the result of the determination process.

According to such a configuration, suitable accommodation position N1 of picker 60 can be guided to the worker, for example, in the initial disposition based on work head 33 suitable for the determined disposition work. Accordingly, it is possible to cause work head 33 suitable for the disposition work to execute the disposition work using picker 60. In addition, even in an aspect in which accommodation position N1 of picker 60 can be replaced between multiple nozzle stations 43 after the initial disposition, the movement distance and the number of times of movement of picker 60 can be reduced.

### 6-5. Moving Section 85

Disposition assistance device 80 may further include moving section 85. Moving section 85 moves picker 60 to nozzle station 43 designated by determination section 83. The operation of replacing pickers 60 among multiple nozzle stations 43 by moving section 85 is not mechanically restricted in a movable range of mounting head 33, but may require permission by the administrator of production system Sy or the operator of component mounter 2.

When the tool replacement operation is allowed, moving section 85 executes the movement process of picker 60 based on the result of the determination process. For example, as illustrated in FIG. 10, moving section 85 sets a period between the disposition work on first side S1 and the disposition work on second side S2, which is a conversion time of first period D1 and second period D2, as moving period Dm suitable for the movement of picker 60. Moving section 85 executes the movement process of picker 60 in moving period Dm.

According to such a configuration, picker 60 can be moved based on mounting head 33 suitable for the disposition work in a series of production. As a result, the efficiency of the setup work involving the disposition work can be improved.

### 7. Disposition Assistance Process of Backup Member 50

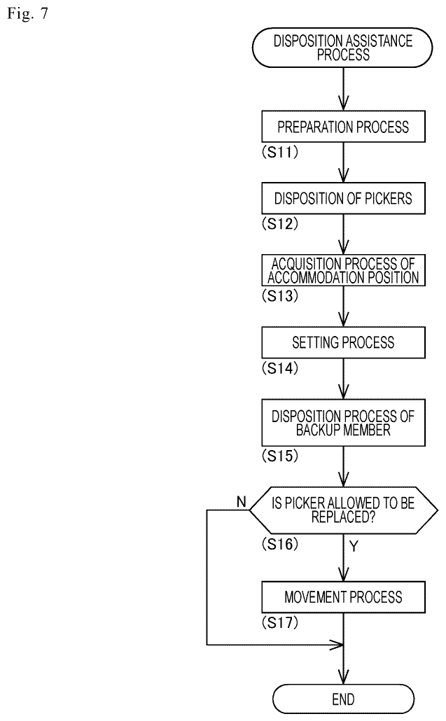

A disposition assistance process by disposition assistance device 80 of backup member 50 will be described with reference to FIGS. 7 to 10. When the board products scheduled to be produced are planned on first side S1 and second side S2 in predetermined production line Ln (production plan M1 in FIG. 9), and the disposition position of backup member 50 is set for each board work corresponding to the production of each board product (disposition information M2 in FIG. 9), disposition assistance device 80 executes the disposition assistance process.

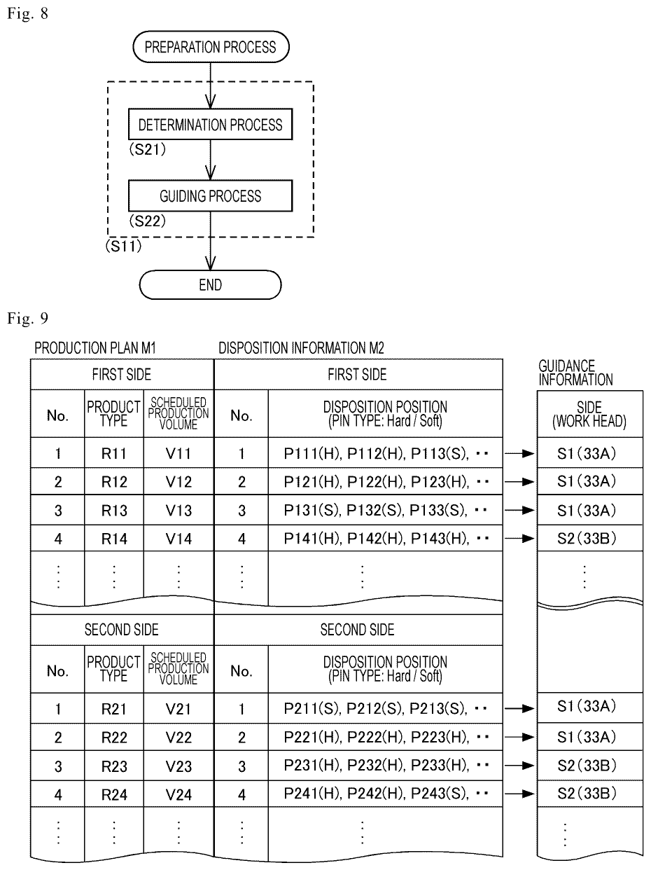

As illustrated in FIG. 7, disposition assistance device 80 first executes a preparation process (S11). In the preparation process, acquisition of information necessary for subsequent processes, recognition of a current state inside component mounter 2, and the like are performed. In an aspect in which disposition assistance device 80 includes determination section 83 and guide section 84, the following processes are executed in the preparation process. As illustrated in FIG. 8, determination section 83 performs the determination process (S21). Accordingly, based on production plan M1 and disposition information M2, as illustrated in FIG. 9, mounting head 33 suitable for each of the multiple disposition works among multiple mounting heads 33 is determined.

Next, guide section 84 executes a guiding process (S22). Accordingly, nozzle station 43 suitable for accommodating picker 60 among multiple nozzle stations 43 in the setup work before production is guided to the worker based on the result of the determination process. For example, the initial disposition of picker 60 is guided to the worker such that picker 60 is accommodated in any accommodation section in nozzle station 43 on first side S1.

Disposition assistance device 80 may download necessary information (production plan M1, disposition information M2, and the like) from host computer 70 or may request the reference to host computer 70 as necessary. When the determination process (S21) or the guiding process (S22) is performed in the preparation process (S11), the process results and the information notified to the worker or the like are each stored in storage section 71 of control device 45 or host computer 70. In an aspect in which disposition assistance device 80 does not include determination section 83 and guide section 84, the above-described processes (S21 and S22) are omitted.

Subsequently, picker 60 is disposed as one of the setup works by the worker (S12). The worker may accommodate picker 60 in nozzle station 43 installed in the machine, or may install nozzle station 43 accommodating picker 60 in the machine. For example, when the side (first side S1 or second side S2) suitable for the initial disposition of picker 60 is guided by the guiding process (S22), the worker may perform the disposition work based on the content of the guide.

After the disposition work of suction nozzle 34 and picker 60 by the worker, acquisition section 81 executes an acquisition process of accommodation position N1 in which picker 60 is accommodated (S13). Specifically, when the production is started after the end of the setup work by the worker, control device 45 of component mounter 2 reads codes 342 and 64 of the tools (suction nozzles 34 and pickers 60) accommodated in all the accommodation sections of multiple nozzle stations 43, and acquires the type of the tool based on the identification information of the tool. Acquisition section 81 acquires accommodation position N1 from the information relating to picker 60 grasped by the reading processing.

Setting section 82 executes a setting process of setting mounting head 33 to execute the disposition work of backup member 50 based on accommodation position N1 of picker 60 (S14). Here, in an aspect in which disposition assistance device 80 does not include determination section 83, setting section 82 determines whether mounting head 33 to be applied to the subsequent disposition work is first mounting head 33A or second mounting head 33B depending on whether accommodation position N1 of picker 60 according to the initial disposition is first side S1 or second side S2.

In an aspect in which disposition assistance device 80 includes determination section 83, setting section 82 sets mounting head 33 to be applied to the subsequent disposition work based on the result of the determination process (S21) in addition to accommodation position N1 of picker 60. At this time, setting section 82 sets mounting head 33 that executes the disposition work such that the time required for the setup work including the disposition work of backup member 50 and the time of the production stop on first side S1 and second side S2 accompanying the execution of the setup work are shortened.

Subsequently, control device 45 executes a disposition process of backup member 50 (S15). Specifically, first, control device 45 causes mounting head 33 set in the setting process (S14) to acquire picker 60 accommodated at accommodation position N1 from nozzle station 43. Then, control device 45 controls the operation of mounting head 33 based on disposition information M2, the position information of backup member 50, and the spare information to dispose backup member 50 of the designated type at the designated position and move the unnecessary backup member 50 to the retract region. By repeating the above operation, the disposition process of backup member 50 is completed.

Here, when picker 60 is allowed to be replaced (moved) among multiple nozzle stations 43 (S16: Yes), disposition assistance device 80 executes the movement process of picker 60 by moving section 85 (S17). Moving section 85 moves picker 60 attached to mounting head 33 to nozzle station 43 on first side S1 or second side S2 based on the result of the determination process (S21). When it is not necessary to move, and when there is no empty accommodation section in nozzle station 43 of the movement destination, moving section 85 does not move picker 60 here, and accommodates picker 60 in the accommodation section of the original nozzle station 43.

Moving section 85 executes the movement process based on the operation status of multiple mounting heads 33, the progress status of the board work, and the like in moving period Dm suitable for the movement of picker 60. Accordingly, as illustrated in FIG. 10, picker 60 is moved to predetermined nozzle station 43 at the end of the disposition process (S15) at an early stage and finally at the start of the disposition work on the opposite side. When the replacement (movement) of picker 60 is restricted (S16: No), the movement process (S17) by moving section 85 is omitted.

When the setup work for all the board work based on production plan M1 is not ended (S18: No), the disposition process (S15), the determination process (S16), and the movement process (S17) according to the progress status of the board work are repeatedly executed. When the setup works of all the board works are ended (S18: Yes), disposition assistance device 80 ends the disposition assistance process. The disposition assistance process corresponds to a disposition assistance method. The acquisition process (S13), the setting process (S14), the determination process (S21), the guiding process (S22), and the movement process (S17) correspond to the acquisition step, the setting step, the determination step, the guiding step, and the movement step, respectively, in the disposition assistance method.

According to the above configuration, work head 33 that performs the disposition work is set in accordance with accommodation position N1 of picker 60, so that the disposition work of backup member 50 can be efficiently performed. As a result, it is possible to prevent a decrease in production efficiency.

### 8. Modification Aspects of Embodiment

In the embodiment, the board work machine has been described as component mounter 2 that mounts components on board 91. On the other hand, disposition assistance device 80 and the disposition assistance method can be applied to a type of a facing robot including multiple work heads among various board work machines. In addition to mounting head 33 that mounts the component by the board work, the work head may apply a bonding member to board 91 or inspect the appearance or function of board 91.

In the embodiment, acquisition section 81, setting section 82, determination section 83, guide section 84, and moving section 85 are incorporated in control device 45. On the other hand, at least a part of above-described sections 81 to 85 may be provided outside control device 45. For example, a part or all of above-described sections 71 to 75 may be configured to be incorporated into host computer 70 or a dedicated external device capable of communicating with the board work machine. Accordingly, the various types of information M1 and M2 are stored in a storage device accessible by each of sections 71 to 75.

### REFERENCE SIGNS LIST

1: printer, 2: component mounter (board work machine), 10, 10A, 10B: board conveyance device, 15, 15A, 15B: backup device, 30, 30A, 30B: component transfer device, 33, 33A, 33B: mounting head (work head), 34: suction nozzle (tool), 42, 42A, 42B: board camera, 43, 43A, 43B: nozzle station (tool station), 45: control device, 50: backup member, 60: picker (tool), 70: host computer, 80: disposition assistance device, 81: acquisition section, 82: setting section, 83: determination section, 84: guide section, 85: moving section, 91: board, M1: production plan, M2: disposition information, N1: accommodation position, S1: first side, S2: second side, Sy: production system

1. A disposition assistance device for a backup member, the disposition assistance device being to be applied to a board work machine configured to automatically exchange a tool among multiple tool stations provided in the machine, the board work machine including multiple work heads configured to execute a predetermined board work using the tool on a board supported by the backup member, the disposition assistance device comprising:
an acquisition section configured to acquire an accommodation position where a picker capable of holding the backup member is accommodated in the multiple tool stations; and
a setting section configured to set the work head that executes a disposition work of the backup member using the picker according to the accommodation position of the picker.

2. The disposition assistance device for a backup member according to claim 1, wherein the acquisition section executes reading processing of codes attached to multiple tools accommodated in the multiple tool stations, and acquires types of the multiple tools including the picker based on a result of the reading processing.

3. The disposition assistance device for a backup member according to claim 2, wherein the acquisition section executes the reading processing of the code using a camera provided to be movable integrally with the work head, and acquires the accommodation position of the tool based on a position of the camera when the camera captures the code.

4. The disposition assistance device for a backup member according to claim 3, wherein the camera is a board camera configured to capture a reference mark attached to the board.

5. The disposition assistance device for a backup member according to claim 1, wherein the setting section sets one of the multiple work heads that is closer to the accommodation position of the picker as the work head that preferentially executes the disposition work.

6. The disposition assistance device for a backup member according to claim 1, further comprising:
an determination section configured to execute a determination process of the work head suitable for each of the disposition works of multiple times among the multiple work heads, based on a production plan indicating a type and a production order of a board product scheduled to be produced, and disposition information indicating a disposition position of the backup member set for the board work corresponding to the production of the board product.

7. The disposition assistance device for a backup member according to claim 6, further comprising:
a guide section configured to guide the tool station accommodating the picker among the multiple tool stations in a setup work before production to a worker executing the setup work based on a result of the determination process.

8. The disposition assistance device for a backup member according to claim 6, wherein the determination section designates the tool station in which the picker is accommodated before execution of the disposition work based on a result of the determination process, and
the disposition assistance device further comprises:
a moving section configured to move the picker to the tool station designated by the determination section.

9. A disposition assistance method for a backup member, the disposition method being to be applied to a board work machine configured to automatically exchange a tool among multiple tool stations provided in the machine, the board work machine including multiple work heads configured to execute a predetermined board work using the tool on a board supported by the backup member, the disposition assistance method comprising:
an acquisition step of acquiring an accommodation position where a picker capable of holding the backup member is accommodated in the multiple tool stations; and
a setting step of setting the work head that executes a disposition work of the backup member using the picker according to the accommodation position of the picker.
